(19) United States
(12) Patent Application Publication
(10) Pub. No.: US 2025/0056721 A1
(43) Pub. Date: Feb. 13, 2025

(54) CIRCUIT BOARD AND MANUFACTURING METHOD THEREOF

(71) Applicants: HongQiSheng Precision Electronics (QinHuangdao) Co., Ltd., Hebei Province (CN); Avary Holding (Shenzhen) Co., Ltd., Shenzhen (CN); Garuda Technology Co., Ltd., New Taipei City (TW)

(72) Inventor: Cheng-Jia LI, Shenzhen (CN)

(21) Appl. No.: 18/457,784

(22) Filed: Aug. 29, 2023

(30) Foreign Application Priority Data
Aug. 11, 2023 (CN) 202311014238.5

(51) Int. Cl. H05K 1/03; H05K 3/46

(52) U.S. Cl. CPC H05K 1/036; H05K 3/4644; H05K 2201/0323; H05K 2201/10977; H05K 2203/1147

(57) ABSTRACT

A circuit board includes a first circuit layer, a second circuit layer, a third circuit layer, a first differential line group, a second differential line group, a third differential line group, and a fourth differential line group. The first differential line group and the third differential line group are disposed between the first circuit layer and the second circuit layer. The second differential line group and the fourth differential line group are disposed between the first circuit layer and the third circuit layer. A first distance between the first differential line group and the first circuit layer is less than a third distance between the third differential line group and the first circuit layer. A second distance between the second differential line group and the first circuit layer is less than a fourth distance between the fourth differential line group and the first circuit layer.

### CROSS-REFERENCE TO RELATED APPLICATION

This application claims priority to China Application Serial Number 202311014238.5, filed Aug. 11, 2023, which is herein incorporated by reference.

### BACKGROUND

### Field of Invention

The present invention relates to a circuit board and a manufacturing method thereof. More particularly, the present invention relates to a circuit board formed of graphene, graphene oxide, and liquid metal and its manufacturing method.

### Description of Related Art

In the technical field of high-frequency transmission lines, via structures are usually used in traditional circuit boards to achieve signal shielding, and the common structures of transmission lines include microstrip structures and stripline structures. However, the via structures would cause impedance discontinuity, and the electromagnetic shielding structure in the microstrip structures and the stripline structures could not achieve shielding of electromagnetic interference (EMI) in all directions.

Furthermore, the roughness of a conductor structure of a circuit board would also affect the effect of signal shielding. If the roughness of the conductor structure may be high, coupled with the skin effect of electrons, it would further increases the loss of the conductor, thereby affecting the effect of signal shielding. In view of the above, there is a need to develop an EMI shielding circuit board in all directions and a manufacturing method thereof to overcome the above disadvantages.

### SUMMARY

At least one embodiment of the present invention provides a circuit board and a manufacturing method thereof. The conductive structure of the differential line of the present invention is made of graphene, and the insulating structure of the differential line is made of graphene oxide. Graphene has the properties of high electrical conductivity, high thermal conductivity, and low roughness, so it can reduce signal loss. Graphene oxide is an insulator, so it can also reduce the impact of roughness on high-frequency signals. The liquid metal of the present invention encapsulates (three-dimensional surrounding) differential lines, so that each of the transmission line groups has an individual shielding structure, thereby achieving shielding of signals in all directions.

A circuit board provided by at least one embodiment of the present invention includes a first circuit layer, a second circuit layer, a third circuit layer, a first differential line group, a second differential line group, a third differential line group, and a fourth differential line group. The first circuit layer is disposed between the second circuit layer and the third circuit layer. The first differential line group is disposed between the first circuit layer and the second circuit layer. The second differential line group is disposed between the first circuit layer and the third circuit layer. The third differential line group is disposed between the first circuit layer and the second circuit layer. The fourth differential line group is disposed between the first circuit layer and the third circuit layer. The first differential line group has a first orthogonal projection on the first circuit layer, the second differential line group has a second orthogonal projection on the first circuit layer, the third differential line group has a third orthogonal projection on the first circuit layer, and the fourth differential line group has a fourth orthogonal projection on the first circuit layer, wherein the first orthogonal projection separates from the third orthogonal projection, and the second orthogonal projection separates from the fourth orthogonal projection. There is a first distance between the first differential line group and the first circuit layer, there is a second distance between the second differential line group and the first circuit layer, there is a third distance between the third differential line group and the first circuit layer, and there is a fourth distance between the fourth differential line group and the first circuit layer, wherein the first distance is less than the third distance, and the second distance is less than the fourth distance.

In at least one embodiment of the present invention, each of the first differential line group, the second differential line group, the third differential line group, and the fourth differential line group includes two differential lines.

In at least one embodiment of the present invention, the aforementioned circuit board further includes a liquid metal structure. The liquid metal structure encapsulates each of the differential lines, wherein the liquid metal structure is distributed among the first circuit layer, the second circuit layer, and the third circuit layer.

In at least one embodiment of the present invention, each of the differential lines includes a conductive structure and an insulating structure.

The conductive structure is made of graphene. The insulating structure surrounds the conductive structure, wherein the insulating structure is made of graphene oxide.

In at least one embodiment of the present invention, the aforementioned circuit board further includes a first insulating layer, a first adhesive layer, a second insulating layer, and a second adhesive layer. The first insulating layer is disposed between the first circuit layer and the second circuit layer, wherein the first insulating layer surrounds the liquid metal structure. The first adhesive layer is disposed between the first insulating layer and the second circuit layer. The second insulating layer is disposed between the first circuit layer and the third circuit layer, wherein the second insulating layer surrounds the liquid metal structure. The second adhesive layer is disposed between the second insulating layer and the third circuit layer.

In at least one embodiment of the present invention, the aforementioned circuit board further includes a sealing member disposed on the second circuit layer, wherein the second circuit layer includes a hole, the hole disposed above the third differential line group, and the sealing member covers the hole.

A manufacturing method of a circuit board provided by at least one embodiment of the present invention includes following steps. A first circuit layer is provided. A first patterned insulating layer is formed on a first surface of the first circuit layer, wherein the first patterned insulating layer includes a plurality of first recesses. A second patterned insulating layer is formed on a second surface of the first circuit layer, wherein the second patterned insulating layer includes a plurality of second recesses, wherein one of the first recesses connects to one of the second recesses. A first liquid metal layer is formed on portions of the first patterned insulating layer. A second liquid metal layer is formed on portions of the second patterned insulating layer. A first differential line group is formed on portions of the first liquid metal layer. A second differential line group is formed on portions of the second liquid metal layer A third patterned insulating layer is formed, wherein the third patterned insulating layer includes a plurality of third recesses, and the first recesses connect to the third recesses. A fourth patterned insulating layer is formed, wherein the fourth patterned insulating layer includes a plurality of fourth recesses, and the second recesses connect to the fourth recesses. A third liquid metal layer is formed on the first differential line group. A fourth liquid metal layer is formed on the second differential line group. A second circuit layer is formed on the first differential line group. A third circuit layer is formed on the second differential line group. After the second circuit layer and the third circuit layer are formed, a liquid metal material is filled into the first, second, third, and fourth recesses. A hole in the second circuit layer is sealed.

In at least one embodiment of the present invention, in the step of forming the third patterned insulating layer includes the following steps. A first insulating layer is formed on the first patterned insulating layer, such that the first recesses are embedded in the first patterned insulating layer to form a plurality of cavities. The first insulating layer is patterned to form the third patterned insulating layer.

In at least one embodiment of the present invention, in the step of forming the first differential line group includes the following steps. A conductive structure is formed on the first liquid metal layer, wherein the conductive structure is made of graphene. An insulating structure is formed on the conductive structure and surrounds the conductive structure, wherein the insulating structure is made of graphene oxide.

In at least one embodiment of the present invention, the aforementioned manufacturing method of the circuit board further includes the following steps. A third differential line group is formed on portions of the third liquid metal layer. A fourth differential line group is formed on portions of the fourth liquid metal layer. A fifth patterned insulating layer is formed, wherein the fifth patterned insulating layer includes a plurality of fifth recesses, and the third recesses connect to the fifth recesses. A sixth patterned insulating layer is formed, wherein the sixth patterned insulating layer includes a plurality of sixth recesses, and the fourth recesses connect to the sixth recesses. A fifth liquid metal layer is formed on the third differential line group. A sixth liquid metal layer is formed on the fourth differential line group, wherein the liquid metal material further fills into the fifth recesses and the sixth recesses.

In at least one embodiment of the present invention, in the step of forming the fifth patterned insulating layer includes the following steps. A second insulating layer is formed on the third patterned insulating layer, such that the first recesses are embedded in the first patterned insulating layer and the third recesses are embedded in the third patterned insulating layer to form a plurality of cavities. The second insulating layer is patterned to form the fifth patterned insulating layer.

In at least one embodiment of the present invention, the first liquid metal layer, the second liquid metal layer, the third liquid metal layer, and the fourth liquid metal layer are formed by sputtering processes.

In at least one embodiment of the present invention, in the step of sealing the hole in the second circuit layer is performed under a normal temperature and a vacuum environment.

In at least one embodiment of the present invention, the first differential line group and the second differential line group are formed by deposition processes.

The circuit board of the present invention has a certain degree of heat resistance in high temperature environment. Because the properties of liquid metal, liquid metal can undergo a phase change reaction in a relatively high temperature environment. The graphene material and the graphene oxide material are respectively used as a transmission line conductor and an insulating layer structure. Therefore, the circuit board of the present disclosure has a design suitable for a higher temperature environment.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 12 are cross-sectional views of a circuit board at various stages of a manufacturing process in accordance with at least one embodiment of the present invention.

### DETAILED DESCRIPTION

In the following text, in order to clearly present the technical features of the present disclosure, the dimensions (such as lengths, widths, thicknesses and depths) of the components (such as insulating layers, circuit layers, and holes, etc.) in the drawings may be enlarged in a non-proportional manner, and the number of some components may be reduced. Therefore, the description and explanation of the following embodiments are not limited to the number of components in the drawings and the size and shape of the components, but should cover the deviations in sizes, shapes and both caused by actual manufacturing processes and/or tolerances. For example, a planar surface shown in the drawings may have rough and/or non-linear features, while acute angles shown in the drawings may be rounded. Therefore, the components shown in the drawings of the present disclosure are mainly for illustration, and are not intended to accurately depict the actual shapes of the components, nor are used to limit the scope of the patent application of the present disclosure.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. That is, when the device is oriented differently from the drawings (rotated 90 degrees or at other orientations), the spatially relative terms used in the present disclosure may also be interpreted accordingly.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

As used herein, “about”, “approximately”, “essentially”, or “substantially” can be used according to optical properties, etching properties, mechanical properties, measurement properties, coating properties or other properties. Accepted deviation ranges or standard deviations are selected, instead of one standard deviation for all properties. It should be noted that a first direction D1 and a second direction D2 are labeled in the drawings to present the configuration relationship of the components in the drawings, and the first direction D1 and the second direction D2 are substantially perpendicular to each other.

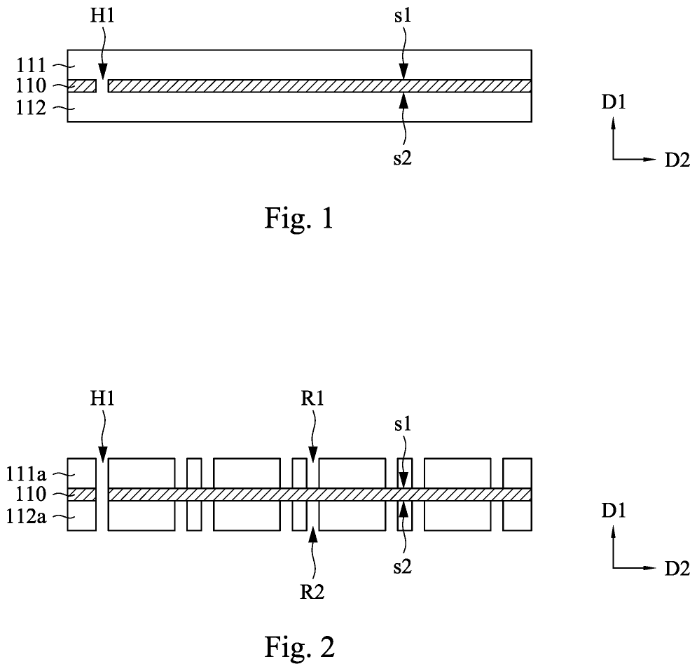

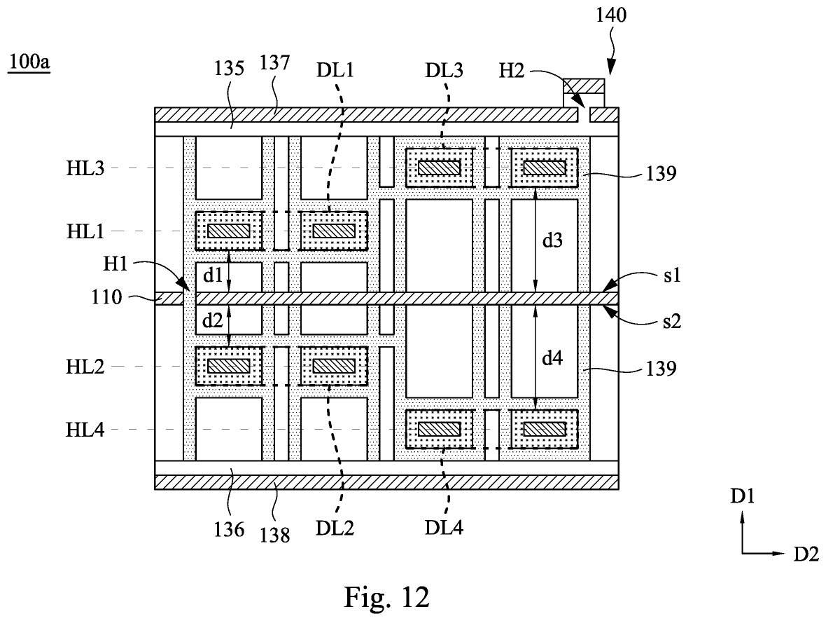

FIG. 1 to FIG. 12 are cross-sectional views of a circuit board 100a at various stages of a manufacturing process in accordance with at least one embodiment of the present invention, in which the circuit board 100a illustrated in FIG. 12. Referring to FIG. 1, the first circuit layer 110 has a first surface s1 and a second surface s2. A first insulating layer 111 is formed on the first surface s1, and a second insulating layer 112 is formed on the second surface s2. In other words, the first circuit layer 110 is interposed between the first insulating layer 111 and the second insulating layer 112. The first circuit layer 110, the first insulating layer 111, and the second insulating layer 112 are stacked along the first direction D1.

In the present embodiment, the first circuit layer 110 is formed by etching a metal layer (such as a copper foil of a copper clad laminate), so the first circuit layer 110 is formed by a subtractive method. As shown in FIG. 1, the first circuit layer 110 has a hole H1. In the present embodiment, the first insulating layer 111 and the second insulating layer 112 are photosensitive insulating materials, such as photo-imageable dielectric (PID). In the present embodiment, the first insulating layer 111 and the second insulating layer 112 are formed on opposite sides of the first circuit layer 110 by laminating processes.

Referring to FIG. 2, the first insulating layer 111 and the second insulating layer 112 are exposed and developed to form a first patterned insulating layer 111a and a second patterned insulating layer 112a, so that the first patterned insulating layer 111a is disposed on the first surface s1 of the first circuit layer 110, and the second patterned insulating layer 112a is disposed on the second surface s2 of the first circuit layer 110. The first patterned insulating layer 111a includes a plurality of first recesses R1, and the second patterned insulating layer 112a includes a plurality of second recesses R2, in which one of the first recesses R1 connects to one of the second recesses R2 through the hole H1, as shown in FIG. 2.

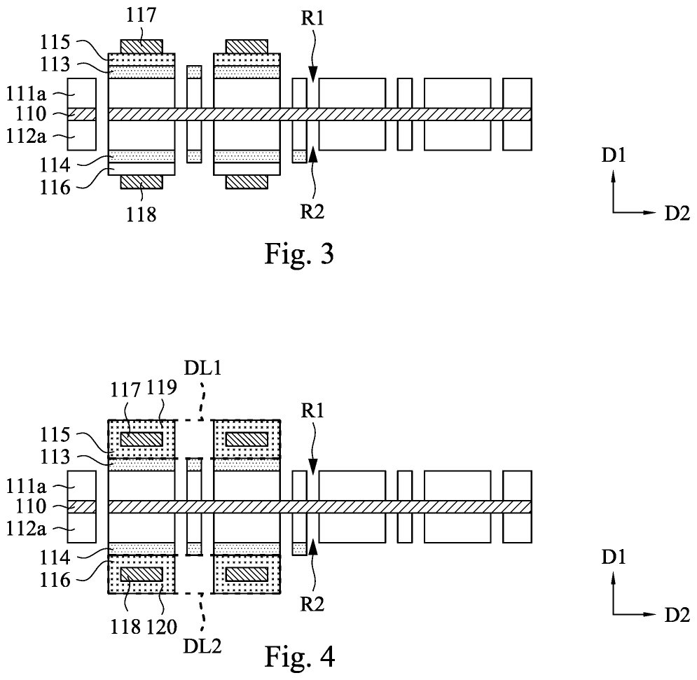

Referring to FIG. 3, a first liquid metal layer 113 is formed on portions of the first patterned insulating layer 111a, and a second liquid metal layer 114 is formed on portions of the second patterned insulating layer 112a, in which the first patterned insulating layer 111a and the second patterned insulating layer 112a are located between the first liquid metal layer 113 and the second liquid metal layer 114. In the present embodiment, the first liquid metal layer 113 and the second liquid metal layer 114 are formed by sputtering processes. In the embodiment of FIG. 3, the first liquid metal layer 113 and the second liquid metal layer 114 are solid at this moment.

In some embodiments, the first liquid metal layer 113 and the second liquid metal layer 114 are made of liquid metals, such as silver (Ag, melting point 961.8° C.), gallium (Ga, melting point 29.76° C.), rubidium (Rb, melting point 38.89° C.), cesium (Cs, melting point 28.44° C.), mercury (Hg, melting point −38.86° C.), francium (Fr, melting point 27° C.), or liquid metals of the above alloys. The property of the liquid metal's phase transition states (that is, the transition between solid state and liquid state) is utilized in the present invention, so that the liquid metal can encapsulate the subsequently formed differential lines.

Still referring to FIG. 3, an insulating layer 115 is formed on the first liquid metal layer 113, and a conductive layer 117 is formed on the insulating layer 115. Similarly, an insulating layer 116 is formed on the second liquid metal layer 114, and a conductive layer 118 is formed on the insulating layer 116. It is noted that, as shown in FIG. 3, a width of the insulating layer 115 is greater than a width of the conductive layer 117, and a width of the insulating layer 116 is greater than a width of the conductive layer 118.

Referring to FIG. 4, an insulating layer 119 covers the conductive layer 117, such that the insulating layer 119 and the insulating layer 115 surround around the conductive layer 117. Similarly, an insulating layer 120 covers the conductive layer 118, such that the insulating layer 120 and the insulating layer 116 surround around the conductive layer 118. Furthermore, the shapes of both the insulating layer 119 and the insulating layer 120 in FIG. 4 may be U-shaped.

In some embodiments, the conductive layer 117 and conductive layer 118 are made of graphene. Graphene has the property of high electrical conductivity, therefore, the conductive layer 117 and the conductive layer 118 are conductive structures with electrical conductivity. It should be noted that the “graphene” material herein includes graphene fiber, graphene film, and graphene aerogel. Because graphene has the properties of high electrical conductivity, high thermal conductivity, and low roughness, it can reduce signal loss. In the present embodiment, a heat-resistant temperature of graphene is about 400° C. In the present embodiment, the conductive layer 117 and the conductive layer 118 are form by deposition processes.

In some embodiments, the insulating layer 119 and the insulating layer 115 are made of graphene oxide (GO), and the insulating layer 120 and the insulating layer 116 are made of graphene oxide. Because graphene oxide is an insulator, it can be understood that the insulating layer 119 and the insulating layer 115 jointly form an insulating structure, and the insulating layer 120 and the insulating layer 116 jointly form an insulating structure. In addition, graphene oxide can reduce the impact of roughness on high-frequency signals due to its structural features, thereby reducing signal loss. In the present embodiment, a heat-resistant temperature of graphene oxide is about 400° C. In the present embodiment, the insulating layer 115, the insulating layer 116, the insulating layer 119, and the insulating layer 120 are formed by deposition processes.

FIG. 4 illustrates two conductive layers 117, two insulating layers 115, and two insulating layers 119 (i.e., two conductive structures and two insulating structures), which may be referred to as a “first differential line group DL1.” In other words, the first differential line group DL1 includes two differential lines, in which the conductive layers 117 shown in FIG. 4 are partial cross-section of the aforementioned differential lines. As shown in FIG. 4, the first differential line group DL1 is disposed on portions of the first liquid metal layer 113.

FIG. 4 illustrates two conductive layers 118, two insulating layers 116, and two insulating layers 120 (i.e., two conductive structures and two insulating structures), which may be referred to as a “second differential line group DL2.” In other words, the second differential line group DL2 includes two differential lines, in which the conductive layers 118 shown in FIG. 4 are partial cross-section of the aforementioned differential lines. As shown in FIG. 4, the second differential line group DL2 is disposed on portions of the second liquid metal layer 114.

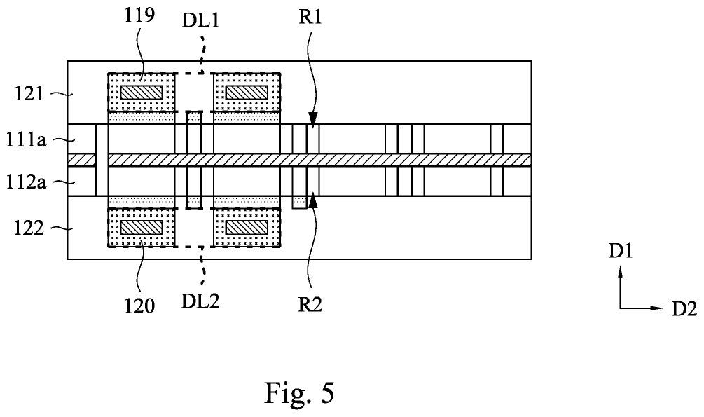

Referring to FIG. 5, a third insulating layer 121 is disposed on the insulating layer 119 and encapsulates the insulating layer 119. The third insulating layer 121 further covers a plurality of first recesses R1, such that the first recesses R1 are embedded in the first patterned insulating layer 111a to form cavities. A fourth insulating layer 122 is formed on the insulating layer 120 and encapsulates the insulating layer 120. The fourth insulating layer 122 further cover the second recesses R2, such that the second recesses R2 are embedded in the second patterned insulating layer 112a to form cavities. In some embodiments, materials of the third insulating layer 121 and the fourth insulating layer 122 are the same as or similar to those of the first insulating layer 111 and the second insulating layer 112. In the present embodiment, the third insulating layer 121 and the fourth insulating layer 122 are formed by laminating processes.

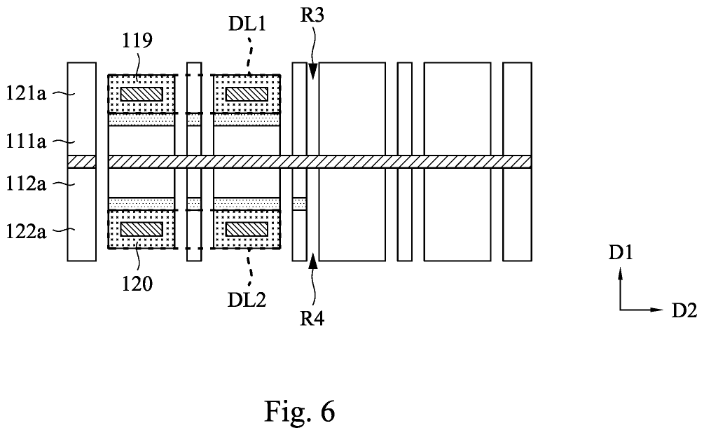

Referring to FIG. 6, the third insulating layer 121 and the fourth insulating layer 122 are exposed and developed to form a third patterned insulating layer 121a and a fourth patterned insulating layer 122a. The third patterned insulating layer 121a includes a plurality of third recesses R3, and the first recesses R1 (referring to FIG. 5) respectively connect to the third recesses R3. The fourth patterned insulating layer 122a includes a plurality of fourth recesses R4, and the second recesses R2 (referring to FIG. 5) respectively connect to the fourth recess R4. It is noted that the third patterned insulating layer 121a exposes the first differential line group DL1, and the fourth patterned insulating layer 122a exposes the second differential line group DL2.

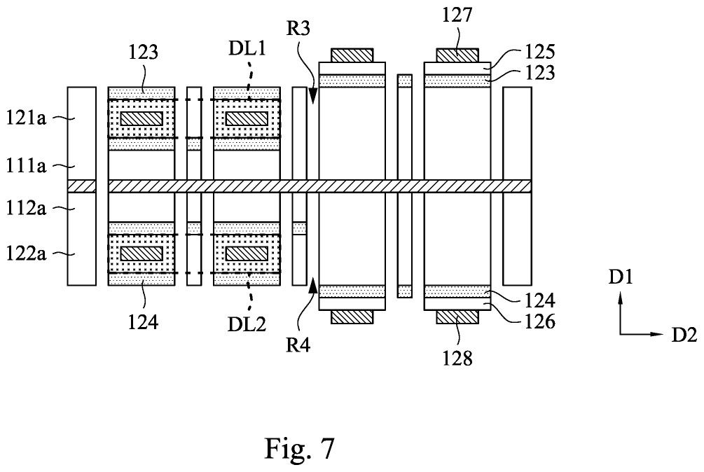

Referring to FIG. 7, a third liquid metal layer 123 is formed on the first differential line group DL1 and covers portions of the third patterned insulating layer 121a (as shown on the right of FIG. 7). A fourth liquid metal layer 124 is formed on the second differential line group DL2 and covers portions of the fourth patterned insulating layer 122a (as shown on the right of FIG. 7). The first differential line group DL1 and the second differential line group DL2 are located between the third liquid metal layer 123 and the fourth liquid metal layer 124. The materials and forming methods of the third liquid metal layer 123 and the fourth liquid metal layer 124 are the same as or similar to those of the first liquid metal layer 113 and the second liquid metal layer 114.

Still referring to FIG. 7, an insulating layer 125 is formed on portions of the third liquid metal layer 123, and a conductive layer 127 is formed on the insulating layer 125. Similarly, an insulating layer 126 is formed on portions of the fourth liquid metal layer 124, and a conductive layer 128 is formed on the insulating layer 126. It is noted that, as shown in FIG. 7, a width of the insulating layer 125 is greater than a width of the conductive layer 127, and a width of the insulating layer 126 is greater than a width of the conductive layer 128.

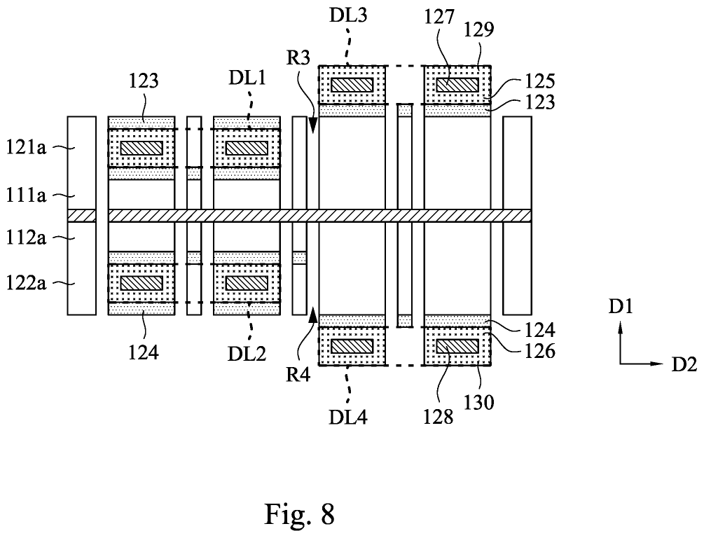

Referring to FIG. 8, an insulating layer 129 covers the conductive layer 127, such that the insulating layer 129 and the insulating layer 125 surround around the conductive layer 127. Similarly, an insulating layer 130 covers the conductive layer 128, such that the insulating layer 130 and the insulating layer 126 surround around the conductive layer 128. Furthermore, the shapes of both the insulating layer 129 and the insulating layer 130 in FIG. 8 may be U-shaped. The conductive layer 127 and the conductive layer 128 are made of graphene. In the present embodiment, the conductive layer 127 and the conductive layer 128 are formed by deposition processes. The insulating layer 125, the insulating layer 126, the insulating layer 129, and the insulating layer 130 are made of graphene oxide. In the present embodiment, the insulating layer 125, the insulating layer 126, the insulating layer 129, and the insulating layer 130 are formed by deposition processes.

FIG. 8 illustrates two conductive layers 127, two insulating layers 125, and two insulating layers 129 (i.e., two conductive structures and two insulating structures), which may be referred to as a “third differential line group DL3.” In other words, the third differential line group DL3 includes two differential lines, in which the conductive layers 127 shown in FIG. 8 are partial cross-section of the aforementioned differential lines. As shown in FIG. 8, the third differential line group DL3 is disposed on portions of the third liquid metal layer 123.

FIG. 8 illustrates two conductive layers 128, two insulating layers 126, and two insulating layers 130 (i.e., two conductive structures and two insulating structures), which may be referred to as a “fourth differential line group DL4.” In other words, the fourth differential line group DL4 includes two differential lines, in which the conductive layers 128 shown in FIG. 8 are partial cross-section of the aforementioned differential lines. As shown in FIG. 8, the fourth differential line group DL4 is disposed on portions of the fourth liquid metal layer 124.

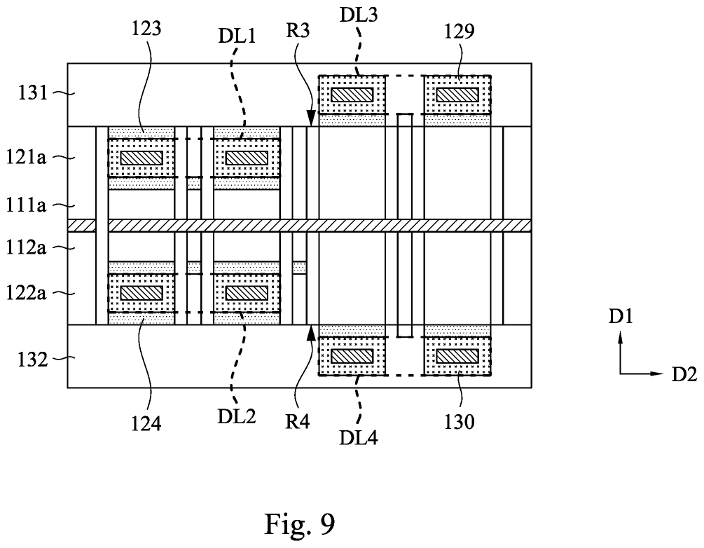

Referring to FIG. 9, a fifth insulating layer 131 is formed on the insulating layer 129 and encapsulates the insulating layer 129. The fifth insulating layer 131 further covers the third recesses R3, such that the third recesses R3 are embedded in the third patterned insulating layer 121a to form cavities. A sixth insulating layer 132 is formed on the insulating layer 130 and encapsulates the insulating layer 130. The sixth insulating layer 132 further covers the fourth recesses R4, such that the fourth recesses R4 are embedded in the fourth patterned insulating layer 122a to form cavities. In some embodiments, materials of the fifth insulating layer 131 and the sixth insulating layer 132 are the same as or similar to those of the first insulating layer 111 and the second insulating layer 112. In the present embodiment, the fifth insulating layer 131 and the sixth insulating layer 132 are formed by laminating processes.

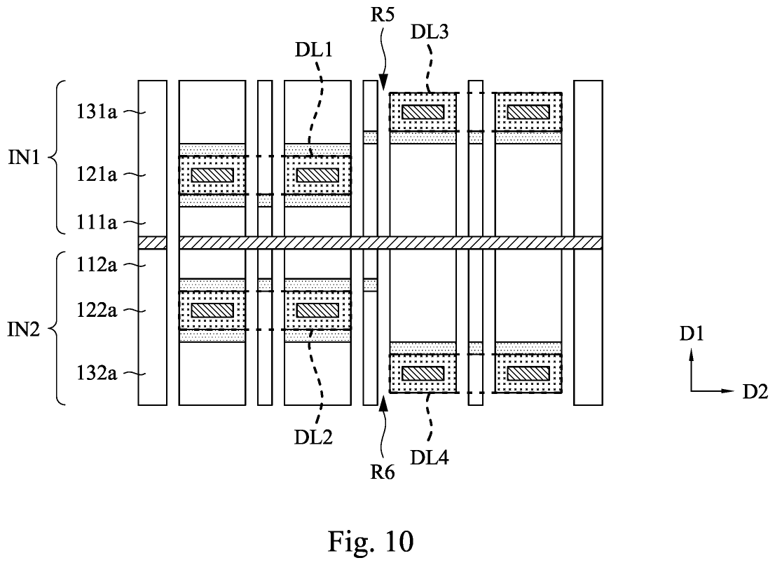

Referring to FIG. 10, the fifth insulating layer 131 and the sixth insulating layer 132 are exposed and developed to form a fifth patterned insulating layer 131a and a sixth patterned insulating layer 132a. It is noted that the fifth patterned insulating layer 131a exposes the third differential line group DL3, and the sixth patterned insulating layer 132a exposes the fourth differential line group DL4.

The fifth patterned insulating layer 131a includes a plurality of fifth recesses R5, and the third recesses R3 (referring to FIG. 9) respectively connect to the fifth recesses R5. The sixth patterned insulating layer 132a includes a plurality of sixth recesses R6, and the fourth recesses R4 (referring to FIG. 9) respectively connect to the sixth recesses R6. In the present embodiment, the first recesses R1 (referring to FIG. 2), the third recesses R3 (referring to FIG. 6), and the fifth recesses R5 (referring to FIG. 10) are aligned with each other, and the second recesses R2 (referring to FIG. 2), the fourth recesses R4 (referring to FIG. 6), and the sixth recesses R6 (referring to FIG. 10) are aligned with each other.

It should be noted that the first patterned insulating layer 111a, the third patterned insulating layer 121a, and the fifth patterned insulating layer 131a may be collectively referred to as an insulating layer IN1. The second patterned insulating layer 112a, the fourth patterned insulating layer 122a, and the sixth patterned insulating layer 132a may be collectively referred to as an insulating layer IN2.

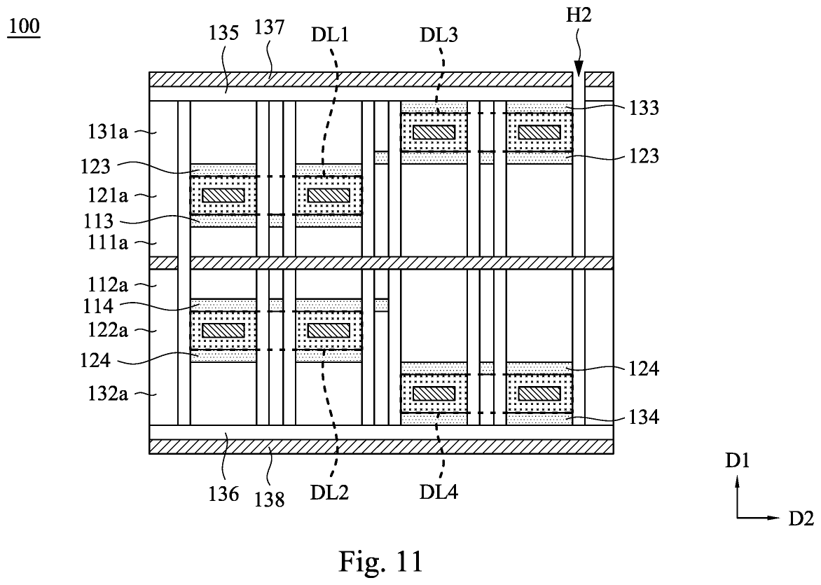

Referring to FIG. 11, a fifth liquid metal layer 133 is formed on the third differential line group DL3, and a sixth liquid metal layer 134 is formed on the fourth differential line group DL4, in which the third differential line group DL3 and the fourth differential line group DL4 are located between the fifth liquid metal layer 133 and the sixth liquid metal layer 134. The materials and forming methods of the fifth liquid metal layer 133 and sixth liquid metal layer 134 are the same as or similar to those of the first liquid metal layer 113 and the second liquid metal layer 114.

Then, a second circuit layer 137 is disposed on the fifth patterned insulating layer 131a and the fifth liquid metal layer 133 through an adhesive layer 135, such that the plurality of recesses (such as the first recesses R1, the third recesses R3, and the fifth recesses R5) are embedded in the patterned insulating layer (such as the insulating layer IN1 in FIG. 10) to form cavities. A third circuit layer 138 is disposed on the sixth patterned insulating layer 132a and the sixth liquid metal layer 134 through an adhesive layer 136, such that the plurality of recesses (such as the second recesses R2, the fourth recesses R4, and the sixth recess R6) are embedded in the patterned insulating layer (such as the insulating layer IN2 in FIG. 10) to form cavities. In the present embodiment, the second circuit layer 137 and the third circuit layer 138 are formed by laminating processes. In some embodiments, materials of the adhesive layer 135 and the adhesive layer 136 are epoxy resin glue or other polymer glue. In some embodiments, the heat-resistant temperature of the adhesive layer 135 and the adhesive layer 136 are in a range from 180° C. to 320° C.

It is noted that the second circuit layer 137 has at least one hole H2, in which the hole H2 connects to one of the fifth recesses R5 (referring to FIG. 10). The hole H2 is a pouring hole for the subsequent liquid metal material 139 (referring to FIG. 12). The aforementioned recesses (such as the first recesses R1 to the sixth recesses R6) are used to fill the subsequent liquid metal material 139 (referring to FIG. 12).

Referring to FIG. 11 and FIG. 12, the liquid metal material 139 is modulated to have a specific fluidity, a specific viscosity, or remain a molten state in a processing environment. The liquid metal material 139 is injected into the plurality of recesses under the condition of a pressurized-environment (the pressure may be adjusted according to the required parameters), and then cools to shape. The liquid metal material 139 can optionally be processed using post-processing steps (for example, infrared heating or sintering) during the injection to make the liquid metal material (including the liquid metal layer) dense, thereby improving reliability.

Specifically, the liquid metal material 139 is filled into the first recesses R1, the second recesses R2, the third recesses R3, the fourth recesses R4, the fifth recesses R5, and the sixth recesses R6 through the hole H2 to form the circuit board 100a shown in FIG. 12, and then cools to shape. More specifically, because the circuit board 100 in FIG. 11 is placed under the pressurized-environment (and optionally using post-processing steps), the first liquid metal layer 113, the second liquid metal layer 114, the third liquid metal layer 123, the fourth liquid metal layer 124, the fifth liquid metal layer 133, and the sixth liquid metal layer 134 have the specific fluidity, the specific viscosity, or remain molten states, such that the plurality of recesses in FIG. 11 are connected to each other.

Then, the liquid metal material 139 flows and fills the plurality of recesses by the height difference of the plurality of recesses (for example, the first recesses R1 to the sixth recesses R6), as shown in FIG. 12. In the present embodiment, the materials of the first liquid metal layer 113 to the sixth liquid metal layer 134 are the same as that of the liquid metal material 139.

It could be understood that after the aforementioned liquid metal material 139 are formed into the plurality of recesses, the temperature is cooling down so that the liquid metal material becomes solid. Therefore, the liquid metal material 139 and the original first liquid metal layer 113 to the sixth liquid metal layer 134 form a liquid metal structure. The liquid metal structure encapsulates each of the differential lines, in which the liquid metal structure distributed among the first circuit layer 110, the second circuit layer 137, and the third circuit layer 138. It should be understood that the term “encapsulate” used herein represents covering at least three planes, such as six planes, of a three-dimensional structure. The insulating layer IN1 and the insulating layer IN2 (referring to FIG. 10) surrounds the liquid metal structure.

Referring to FIG. 12, after the aforementioned liquid metal material 139 are filled into the plurality of recesses, the hole H2 in the second circuit layer 137 are sealed by using a sealing member 140. In some embodiments, in the step of sealing the hole H2 in the second circuit layer 137 is performed under a normal temperature and a vacuum environment.

Because each of the differential lines are all encapsulated by the liquid metal structure, each of the differential line groups has an individual shielding structure, thereby reducing signal loss. Furthermore, the liquid metal structure connects to the first circuit layer 110, the second circuit layer 137, and the third circuit layer 138, such that the liquid metal structure is grounded, so the structure of the circuit board 100a can be improved, thereby reducing signal loss.

Please refer to FIG. 12 again. The circuit board 100a includes the first circuit layer 110, the second circuit layer 137, the third circuit layer 138, the first differential line group DL1, the second differential line group DL2, the third differential line group DL3, and the fourth differential line group DL4. The first circuit layer 110 is disposed between the second circuit layer 137 and the third circuit layer 138. The first differential line group DL1 is disposed between the first circuit layer 110 and the second circuit layer 137. The second differential line group DL2 is disposed between the first circuit layer 110 and the third circuit layer 138. The third differential line group DL3 is disposed between the first circuit layer 110 and the second circuit layer 137. The fourth differential line group DL4 is disposed between the first circuit layer 110 and the third circuit layer 138.

As shown in FIG. 12, the first differential line group DL1 is arranged along a first horizontal line HL1, the second differential line group DL2 is arranged along a second horizontal line HL2, the third differential line group DL3 is arranged along a third horizontal line HL3, and the fourth differential line group DL4 is arranged along a fourth horizontal line HL4. The first horizontal line HL1, the second horizontal line HL2, the third horizontal line HL3, and the fourth horizontal line HL4 extend along a direction parallel to the second direction D2, and the first horizontal line HL1, the second horizontal line HL2, the third horizontal line HL3, and the fourth horizontal line HL4 are separated from each other. The third horizontal line HL3 is higher than the first horizontal line HL1, the first horizontal line HL1 is higher than the second horizontal line HL2, and the second horizontal line HL2 is higher than the fourth horizontal line HL4.

In other words, the first differential line group DL1 to the fourth differential line group DL4 have height differences, such that each of the differential line groups is not on the same plane, thereby signal interference between the differential lines (transmission lines) can be avoided. As shown in FIG. 12, the first differential line group DL1 to the fourth differential line group DL4 have a mirror-symmetrical structure taking the first circuit layer 110 as the symmetry axis. Each of the first differential line group DL1 to fourth differential line group DL4 may have different functions, for example, different transmission frequencies. In some embodiments, the thickness of the conductive structure (such as the conductive layer 117, the conductive layer 118, the conductive layer 127, and the conductive layer 128) of each of the first differential line group DL1 to the fourth differential line group DL4 may be different.

Referring to FIG. 12, the first differential line group DL1 has a first orthogonal projection (not shown) on the first circuit layer 110, the second differential line group DL2 has a second orthogonal projection (not shown) on the first circuit layer 110, the third differential line group DL3 has a third orthogonal projection (not shown) on the first circuit layer 110, and the fourth differential line group DL4 has a fourth orthogonal projection (not shown) on the first circuit layer 110, in which the first orthogonal projection separates from the third orthogonal projection, and the second orthogonal projection separates from the fourth orthogonal projection.

It could be understood that the term “orthogonal projection” herein represents the projections of the first differential line group DL1 to the fourth differential line group DL4 on the first surface s1 or the second surface s2 of the first circuit layer 110 along the direction parallel to the first direction D1. It is like a virtual light beam that is parallel to the first direction D1, and the virtual light beam irradiate the projections of the first differential line group DL1 to the fourth differential line group DL4 on the first surface s1 or the second surface s2 of the first circuit layer 110.

As shown in FIG. 12, there is a first distance d1 between the first differential line group DL1 and the first circuit layer 110, there is a second distance d2 between the second differential line group DL2 and the first circuit layer 110, there is a third distance d3 between the third differential line group DL3 and the first circuit layer 110, and there is a fourth distance d4 between the fourth differential line group DL4 and the first circuit layer 110, in which the first distance d1 is less than the third distance d3, and the second distance d2 is less than the fourth distance d4. In some embodiments, the first distance d1 is substantially equal to the second distance d2, and the third distance d3 is substantially equal to the fourth distance d4.

Based on the above, the conductive structure of the differential line of the present invention is made of graphene, and the insulating structure of the differential line is made of graphene oxide. Graphene has the properties of high electrical conductivity, high thermal conductivity, and low roughness, so it can reduce signal loss. Graphene oxide is an insulator, so it can also reduce the impact of roughness on high-frequency signals. The liquid metal of the present invention encapsulates (three-dimensional surrounding) differential lines, so that each of the transmission line groups has an individual shielding structure, thereby achieving shielding of signals in all directions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit board, comprising:
a first circuit layer;
a second circuit layer;
a third circuit layer, wherein the first circuit layer is disposed between the second circuit layer and the third circuit layer;
a first differential line group disposed between the first circuit layer and the second circuit layer;
a second differential line group disposed between the first circuit layer and the third circuit layer;
a third differential line group disposed between the first circuit layer and the second circuit layer; and
a fourth differential line group disposed between the first circuit layer and the third circuit layer,
wherein the first differential line group has a first orthogonal projection on the first circuit layer, the second differential line group has a second orthogonal projection on the first circuit layer, the third differential line group has a third orthogonal projection on the first circuit layer, and the fourth differential line group has a fourth orthogonal projection on the first circuit layer, wherein the first orthogonal projection separates from the third orthogonal projection, and the second orthogonal projection separates from the fourth orthogonal projection,
wherein there is a first distance between the first differential line group and the first circuit layer, there is a second distance between the second differential line group and the first circuit layer, there is a third distance between the third differential line group and the first circuit layer, and there is a fourth distance between the fourth differential line group and the first circuit layer, wherein the first distance is less than the third distance, and the second distance is less than the fourth distance.

2. The circuit board of claim 1, wherein each of the first differential line group, the second differential line group, the third differential line group, and the fourth differential line group comprises two differential lines.

3. The circuit board of claim 2, further comprising:
a liquid metal structure encapsulating each of the differential lines, wherein the liquid metal structure is distributed among the first circuit layer, the second circuit layer, and the third circuit layer.

4. The circuit board of claim 2, wherein each of the differential lines comprising:
a conductive structure, wherein the conductive structure is made of graphene; and
an insulating structure surrounding the conductive structure, wherein the insulating structure is made of graphene oxide.

5. The circuit board of claim 3, wherein each of the differential lines comprising:
a conductive structure, wherein the conductive structure is made of graphene; and
an insulating structure surrounding the conductive structure, wherein the insulating structure is made of graphene oxide.

6. The circuit board of claim 3, further comprising:
a first insulating layer disposed between the first circuit layer and the second circuit layer, wherein the first insulating layer surrounds the liquid metal structure;
a first adhesive layer disposed between the first insulating layer and the second circuit layer;
a second insulating layer disposed between the first circuit layer and the third circuit layer, wherein the second insulating layer surrounds the liquid metal structure; and
a second adhesive layer disposed between the second insulating layer and the third circuit layer.

7. The circuit board of claim 1, further comprising:
a sealing member disposed on the second circuit layer, wherein the second circuit layer comprises a hole, the hole disposed above the third differential line group, and the sealing member covers the hole.

8. A manufacturing method of a circuit board, comprising:
providing a first circuit layer;
forming a first patterned insulating layer on a first surface of the first circuit layer, wherein the first patterned insulating layer comprises a plurality of first recesses;
forming a second patterned insulating layer on a second surface of the first circuit layer, wherein the second patterned insulating layer comprises a plurality of second recesses, wherein one of the first recesses connects to one of the second recesses;
forming a first liquid metal layer on portions of the first patterned insulating layer;
forming a second liquid metal layer on portions of the second patterned insulating layer;
forming a first differential line group on portions of the first liquid metal layer;
forming a second differential line group on portions of the second liquid metal layer;
forming a third patterned insulating layer, wherein the third patterned insulating layer comprises a plurality of third recesses, and the first recesses connect to the third recesses;
forming a fourth patterned insulating layer, wherein the fourth patterned insulating layer comprises a plurality of fourth recesses, and the second recesses connect to the fourth recesses;
forming a third liquid metal layer on the first differential line group;
forming a fourth liquid metal layer on the second differential line group;
forming a second circuit layer on the first differential line group;
forming a third circuit layer on the second differential line group;
after forming the second circuit layer and the third circuit layer, filling a liquid metal material into the first, second, third, and fourth recesses; and
sealing a hole in the second circuit layer.

9. The manufacturing method of the circuit board of claim 8, wherein in the step of forming the third patterned insulating layer comprises:
forming a first insulating layer on the first patterned insulating layer, such that the first recesses are embedded in the first patterned insulating layer to form a plurality of cavities; and
patterning the first insulating layer to form the third patterned insulating layer.

10. The manufacturing method of the circuit board of claim 8, wherein in the step of forming the first differential line group comprises:
forming a conductive structure on the first liquid metal layer, wherein the conductive structure is made of graphene; and
forming an insulating structure on the conductive structure, wherein the insulating structure surrounds the conductive structure, and the insulating structure is made of graphene oxide.

11. The manufacturing method of the circuit board of claim 8, further comprising:
forming a third differential line group on portions of the third liquid metal layer;
forming a fourth differential line group on portions of the fourth liquid metal layer;
forming a fifth patterned insulating layer, wherein the fifth patterned insulating layer comprises a plurality of fifth recesses, and the third recesses connect to the fifth recesses;
forming a sixth patterned insulating layer, wherein the sixth patterned insulating layer comprises a plurality of sixth recesses, and the fourth recesses connect to the sixth recesses;
forming a fifth liquid metal layer on the third differential line group; and
forming a sixth liquid metal layer on the fourth differential line group, wherein the liquid metal material further fills into the fifth recesses and the sixth recesses.

12. The manufacturing method of the circuit board of claim 11, wherein in the step of forming the fifth patterned insulating layer comprises:
forming a second insulating layer on the third patterned insulating layer, such that the first recesses are embedded in the first patterned insulating layer and the third recesses are embedded in the third patterned insulating layer to form a plurality of cavities; and
patterning the second insulating layer to form the fifth patterned insulating layer.

13. The manufacturing method of the circuit board of claim 8, wherein the first liquid metal layer, the second liquid metal layer, the third liquid metal layer, and the fourth liquid metal layer are formed by sputtering processes.

14. The manufacturing method of the circuit board of claim 8, wherein in the step of sealing the hole in the second circuit layer is performed under a normal temperature and a vacuum environment.

15. The manufacturing method of the circuit board of claim 8, wherein the first differential line group and the second differential line group are formed by deposition processes.
